(19) United States
(12) Patent Application Publication
(10) Pub. No.: US 2025/0290986 A1
(43) Pub. Date: Sep. 18, 2025

(54) BATTERY CLASSIFICATION METHOD, BATTERY MODULE MANUFACTURING METHOD, AND BATTERY CLASSIFICATION SYSTEM

(71) Applicant: TOYOTA JIDOSHA KABUSHIKI KAISHA, Toyota-shi (JP)

(72) Inventor: Takayuki MIYAJIMA, Nagoya-shi (JP)

(73) Assignee: TOYOTA JIDOSHA KABUSHIKI KAISHA, Toyota-shi (JP)

(21) Appl. No.: 18/976,365

(22) Filed: Dec. 11, 2024

(30) Foreign Application Priority Data
Mar. 14, 2024 (JP) 2024-040226

(51) Int. Cl. G01R 31/367; H01M 10/42

(52) U.S. Cl. CPC G01R 31/367; H01M 10/4207; H01M 10/4221; H01M 2010/4292

(57) ABSTRACT

A method of classifying a battery includes causing a computer to perform the following steps. Obtaining the manufacturing conditions of the plurality of batteries, predicting the durability performance of the plurality of batteries from the obtained manufacturing conditions based on the relationship between the manufacturing conditions of the batteries and the durability performance of the batteries, and classifying the plurality of batteries based on the similarity of the predicted durability performance. The method of the present disclosure for manufacturing a battery module includes connecting batteries having similar durability performance classified according to the method of the present disclosure for classifying batteries in parallel or in series.

### CROSS-REFERENCE TO RELATED APPLICATION

This application claims priority to Japanese Patent Application No. 2024-040226 filed on Mar. 14, 2024, incorporated herein by reference in its entirety.

### BACKGROUND

### 1. Technical Field

The present disclosure relates to a battery classification method, a battery module manufacturing method, and a battery classification system.

### 2. Description of Related Art

A technique of using a plurality of batteries in combination in order to obtain a desired battery capacity is known.

Japanese Unexamined Patent Application Publication No. 2009-240154 (JP 2009-240154 A), for example, discloses a method of controlling charge and discharge of a plurality of batteries, in which the life of the batteries can be increased by averaging the deterioration of the batteries by making the use condition of the batteries uniform.

### SUMMARY

The disclosers of the present matter have found that the durability performance of a plurality of batteries may be different even if the performance of the batteries such as input and output characteristics is equivalent at the time of the shipping inspection, for example, when the batteries are used in combination.

An object of the present disclosure is to provide a battery classification method based on the difference in durability performance for a case where a plurality of batteries is used in combination, a battery module manufacturing method including such a method, and a battery classification system.

The disclosers of the present matter have found that the above issue can be addressed by the following means.

### First Aspect

A battery classification method including causing a computer to execute a process including:
acquiring a manufacturing condition for a plurality of batteries;
predicting durability performance of the batteries from the acquired manufacturing condition based on relationship between the manufacturing condition of the batteries and the durability performance of the batteries; and
classifying the batteries based on similarity of the durability performance that has been predicted.

### Second Aspect

The method according to the first aspect, in which
the manufacturing condition is a dew point of an atmosphere at a time when a positive electrode mixture and/or a negative electrode mixture is laminated on a base material, or a ratio of a basis weight of the positive electrode mixture to a basis weight of the negative electrode mixture.

### Third Aspect

The method according to the first aspect, in which
the relationship is relationship specified in advance through machine learning.

### Fourth Aspect

A battery module manufacturing method including
connecting the batteries having similar durability performance and classified by the method according to any one of the first to third aspects in parallel or in series with each other.

### Fifth Aspect

A battery classification system including:
an acquisition unit that acquires a manufacturing condition for a plurality of batteries;
a prediction unit that predicts durability performance of the batteries from the manufacturing condition acquired by the acquisition unit based on relationship between the manufacturing condition of the batteries and the durability performance of the batteries; and
a classification unit that classifies the batteries based on similarity of the durability performance predicted by the prediction unit.

According to the present disclosure, it is possible to provide a battery classification method based on the difference in durability performance for a case where a plurality of batteries is used in combination, a battery module manufacturing method including such a method, and a battery classification system.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a flow chart illustrating a method of the present disclosure for classifying batteries;

FIG. 2 is a graph showing an exemplary relation between a dew point (positive electrode lamination environmental dew point) and a SHAP when a positive electrode mixture is laminated on a base material;

FIG. 3 is a graph showing an exemplary relation between a dew point (negative electrode lamination environmental dew point) and a SHAP when a negative electrode mixture is laminated on a base material;

FIG. 4 is a graph showing an exemplary relationship between the ratio of the weight of the positive electrode composite material to the weight of the negative electrode composite material (positive electrode weight/negative electrode weight) and SHAP;

FIG. 5A is a schematic diagram illustrating a battery module connected in parallel by the disclosed methods of manufacturing a battery module;

FIG. 5B is a schematic diagram illustrating a battery module connected in series according to the disclosed methods of manufacturing a battery module; and

FIG. 6 is a schematic diagram illustrating an example of a battery classification system of the present disclosure.

### DETAILED DESCRIPTION OF EMBODIMENTS

Hereinafter, embodiments of the present disclosure will be described in detail. It should be noted that the present disclosure is not limited to the following embodiments, and various modifications can be made within the scope of the gist of the disclosure.

### Battery Classification Method

The method of the present disclosure for classifying a battery includes causing a computer to perform the following steps.
Obtaining manufacturing conditions for a plurality of batteries,
Predicting the durability performance of the plurality of batteries from the obtained manufacturing conditions based on the relationship between the manufacturing conditions of the batteries and the durability performance of the batteries; and
To classify a plurality of batteries based on a degree of similarity of predicted durability performance.

The Disclosing Party considered that one of the reasons why the durability performance of each battery may differ in the case where a plurality of batteries are used in combination lies in the manufacturing conditions of the battery. Therefore, the Disclosing Party, etc. examined the correlation between manufacturing conditions and durability performance by machine learning. More specifically, a LightGBM which is one of the data-analysis methods called “supervised learning” was constructed, and correlations were examined by extracting manufacturing conditions as explanatory variables with higher SHAP for durability performance as objective variables. SHAP indicates the contribution of the explanatory variable to the objective variable.

The inventors of the present disclosure have found that the durability performance of a plurality of batteries can be predicted from the manufacturing conditions obtained as actual measurement values based on the relationship between the manufacturing conditions of the batteries identified in this manner and the durability performance of the batteries. Further, the present disclosure has found that by classifying a plurality of batteries based on the similarity degree of durability performance predicted in this way, it is possible to use a combination of batteries having similar durability performance.

The battery used in the present disclosure may be, for example, a lithium-ion secondary battery. Applications of batteries include, for example, power supplies for vehicles such as hybrid electric vehicle (HEV), plug-in hybrid electric vehicle (PHEV), battery electric vehicle (BEV), gasoline-powered vehicles, and diesel-powered vehicles. In particular, it is preferably used as a power supply for driving of hybrid electric vehicle (HEV), plug-in hybrid electric vehicle (PHEV), or battery electric vehicle (BEV). Also, the battery in the present disclosure may be used as a power source for mobile bodies other than vehicles (for example, railroads, ships, and aircraft), and may be used as a power source for electric products such as an information processing device.

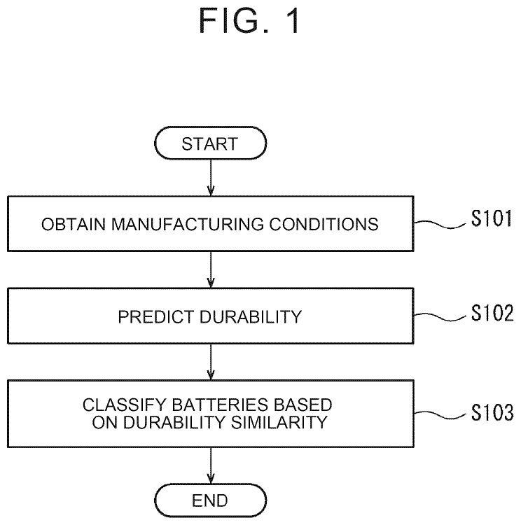

FIG. 1 is a flow chart illustrating a method of the present disclosure for classifying batteries. Hereinafter, each step of the method of the present disclosure for classifying a battery will be described with reference to FIG. 1.

### Manufacturing Conditions Acquisition Process

As shown in FIG. 1, the disclosed methods include causing a computer to execute a process of obtaining manufacturing conditions for a plurality of batteries (S101).

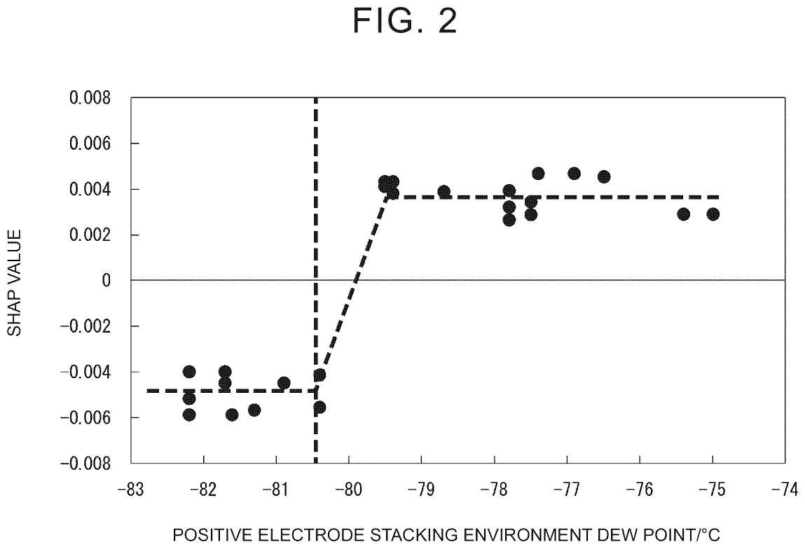

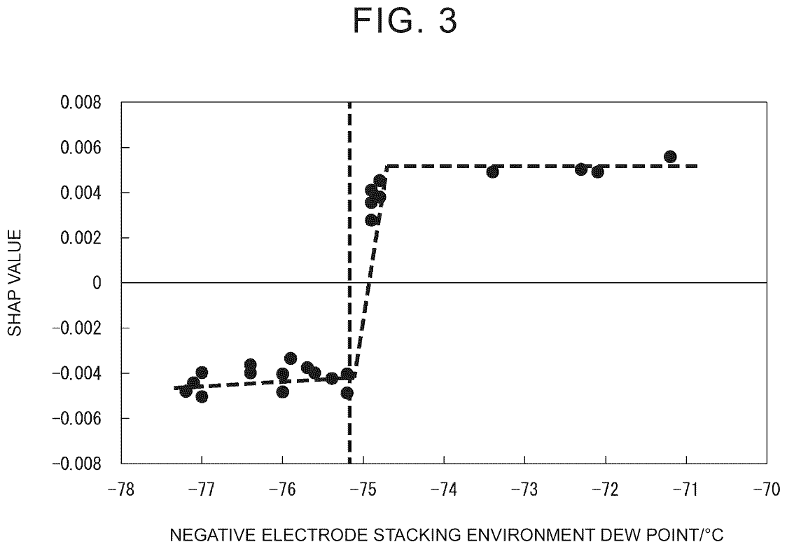

The manufacturing condition may be a dew point of an atmosphere in laminating the positive electrode mixture and/or the negative electrode mixture to the base material. Here, FIG. 2 is a graph showing an exemplary relation between the dew point and SHAP of the atmosphere when the positive electrode mixture is laminated on the base material. FIG. 3 is a graph showing an exemplary relation between the dew point and SHAP of the atmosphere when the negative electrode mixture is laminated on the base material.

According to studies by the Disclosing Party, as illustrated in FIG. 2, the dew point of the atmosphere when the positive electrode mixture is laminated on the base material is correlated with SHAP, that is, the degree of contribution of the dew point to the durability performance. More specifically, in a case where a predetermined material is used and a condition other than the dew point is examined under a predetermined condition, the durability performance of a plurality of batteries is different from each other with a threshold value of −80.5° C. That is, when the dew point was −80.5° C. or lower, the durability performance of the battery was high, and when the dew point was higher than −80.5° C., the durability performance of the battery was low.

Further, as illustrated in FIG. 3, the dew point of the atmosphere when the negative electrode mixture is laminated on the base material is correlated with SHAP, that is, the degree of contribution of the dew point to the durability performance. More specifically, in a case where a predetermined material is used and a condition other than the dew point is examined under a predetermined condition, the durability performance of a plurality of batteries is different from each other with a threshold value of −75° C. That is, when the dew point was −75° C. or lower, the durability performance of the battery was high, and when the dew point was higher than −75° C., the durability performance of the battery was low.

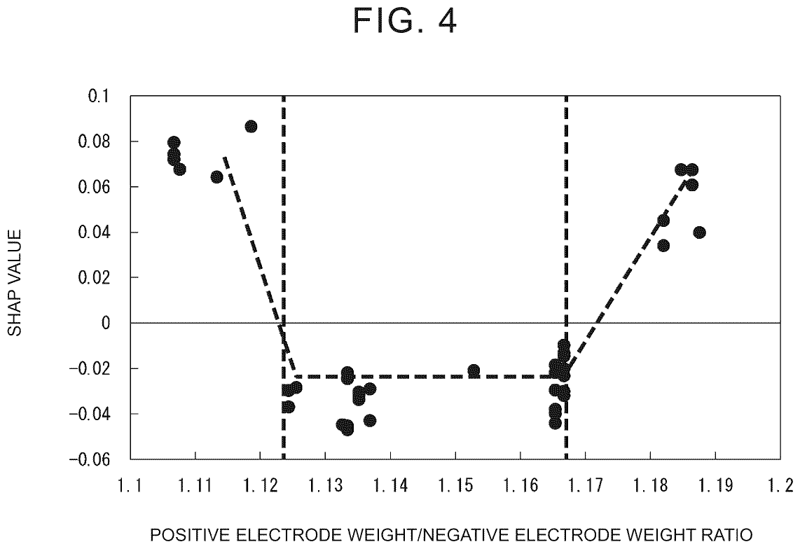

Manufacturing conditions may be a ratio of the noticeable amount of the positive coating material to the noticeable amount of the negative coating material. FIG. 4 is a graph showing an exemplary relation between the ratio of the grooved quantity of the positive electrode composite material to the grooved quantity of the negative electrode composite material and SHAP. In the present disclosure, the basis weight means the mass of the electrode mixture per unit area.

According to the examination by the Disclosing Party, as illustrated in FIG. 4, the ratio of the basis weight of the positive electrode mixture to the basis weight of the negative electrode mixture is correlated with SHAP, that is, the contribution of the ratio to the durability performance. More specifically, in a case where a predetermined material is used and a predetermined condition is examined except for the above-described ratio, a difference in durability performance occurs with 1.123 and 1.167 as threshold values. That is, when the ratio is 1.123 or more and 1.167 or less, the durability performance is high, and when the ratio is smaller than 1.123 and larger than 1.167, the durability performance is low.

Examples of a method of laminating the positive electrode mixture and the negative electrode mixture on the base material include a method of preparing a mixture slurry obtained by adding a dispersion medium to each mixture and applying the mixture slurry to the base material to dry the mixture slurry.

In the context of the present disclosure, “mixture” means a composition that can constitute a positive electrode active material layer or a negative electrode active material as it is or by further containing other components. In addition, in the context of the present disclosure, a “mixture slurry” means a slurry that includes a dispersion medium in addition to a “mixture” and can thereby be applied and dried to form a positive electrode active material layer or a negative electrode active material layer.

### Endurance Performance Prediction Process

As shown in FIG. 1, the disclosed methods include causing a computer to perform a process of predicting durability performance of a plurality of batteries from the acquired manufacturing conditions based on a relation between the manufacturing conditions of the batteries and the durability performance of the batteries (S102).

In the method of the present disclosure, the relationship between the manufacturing conditions of the battery and the durability performance of the battery may be a relationship specified in advance by machine learning, and specifically, may be a relationship based on the graph illustrated in FIGS. 2 to 4 described above.

For example, based on the graph illustrated in FIG. 2, it is possible to predict the durability performance of a plurality of batteries from the dew point of the atmosphere at the time of laminating the positive electrode mixture material obtained in the manufacturing condition obtaining step to the base material. That is, as shown in FIG. 2, when the dew point is less than or equal to −80.5° C., which is the threshold value, it can be predicted that the durability performance is high. If the dew point is greater than −80.5° C., it can be predicted that the durability performance is low.

Based on the graph illustrated in FIG. 3, the durability performance of the plurality of batteries can be predicted from the dew point of the atmosphere when the negative electrode mixture obtained in the manufacturing condition obtaining step is laminated on the base material. That is, as shown in FIG. 3, when the dew point is −75° C. or less, which is a threshold value, it can be predicted that the durability performance is high. If the dew point is greater than −75° C., it can be predicted that the durability performance is low.

Based on the graph illustrated in FIG. 4, the durability performance of the plurality of batteries can be predicted from the ratio of the basis weight of the positive electrode mixture to the basis weight of the negative electrode mixture obtained in the manufacturing condition obtaining step. That is, as shown in FIG. 4, when the ratio is 1.123 or more and 1.167 or less, which is a threshold value, it can be predicted that the durability performance is high. If the ratio is less than 1.12 and greater than 1.167, it can be predicted that the durability performance is low.

### Battery Classification Process

As shown in FIG. 1, the disclosed methods include classifying a plurality of batteries based on the similarity in the predicted durability performance (S103).

In the method of the present disclosure, the degree of similarity in durability performance can be determined based on the graph illustrated in FIGS. 2 to 4 described above.

For example, based on the graph illustrated in FIG. 2, SHAP can be set to −0.004 when the dew point of the atmosphere at the time of laminating the positive electrode mixture to the base material is less than or equal to −80.5° C., which is the threshold. Further, based on the graph illustrated in FIG. 2, SHAP when the dew point of the atmosphere when the positive electrode mixture is laminated on the base material is greater than −80.5° C. can be set to 0.004. In this case, it can be determined that the batteries having the same SHAP have similar durability performance. This makes it possible to classify a plurality of batteries based on the degree of similarity in durability performance.

Based on the graph illustrated in FIG. 3, SHAP can be set to −0.005 when the dew point of the atmosphere at the time of laminating the negative electrode mixture to the base material is −75° C. or less, which is the threshold value. Further, based on the graph illustrated in FIG. 3, SHAP can be set to 0.004 when the dew point of the atmosphere at the time of laminating the negative electrode mixture to the base material is greater than −75° C. In this case, it can be determined that the plurality of batteries having the same SHAP have similar durability performance. This makes it possible to classify a plurality of batteries based on the degree of similarity in durability performance.

In addition, a plurality of batteries can be classified as follows from SHAP set as described above based on the dew point of the atmosphere when both the positive electrode mixture and the negative electrode mixture are laminated on the base material.

SHAP=−0.009 Rank A

−0.009<SHAP<0.008 Rank B

SHAP=0.008 Rank C

Here, SHAP is obtained by adding the dew point of the atmosphere when the positive electrode mixture is laminated on the base material and the dew point of the atmosphere when the negative electrode mixture is laminated on the base material. In addition, rank A, rank B, and rank C are set in descending order of durability performance.

On the basis of the graph illustrated in FIG. 4, SHAP when the ratio of the basis weight of the positive electrode mixture to the basis weight of the negative electrode mixture is equal to or greater than 1.123 and equal to or less than 1.167, which is the threshold value, can be set to −0.02. Also, based on the plot illustrated in FIG. 4, SHAP may be set to 0.07 when the percentage is less than 1.123. Based on the plot illustrated in FIG. 4, SHAP may be set to 0.06 if this percentage is greater than 1.167. In this case, it can be determined that the batteries having the same SHAP have similar durability performance. This makes it possible to classify a plurality of batteries based on the degree of similarity in durability performance.

In addition, a plurality of batteries can be classified from SHAP set as described above as follows.

SHAP=−0.02 Rank A

SHAP≤0.06 Rank B.

In this case, ranks A and B are set in descending order of durability performance.

### Battery Module Manufacturing Method

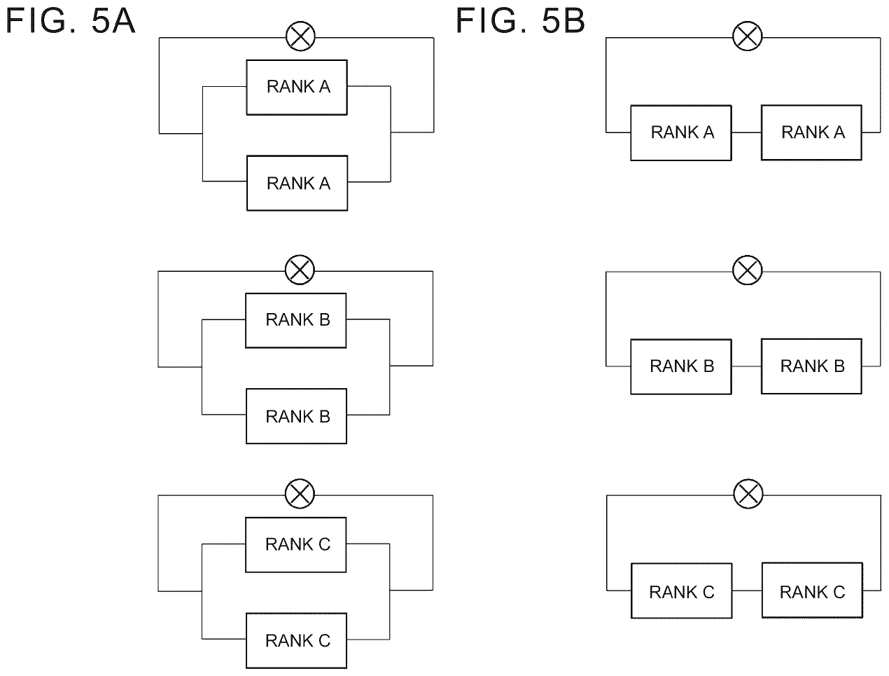

As illustrated in FIGS. 5A and 5B, the method of the present disclosure for manufacturing a battery module includes connecting batteries having similar durability performance classified according to the method of the present disclosure for classifying batteries in parallel or in series. Note that FIG. 5A is a schematic diagram illustrating an example of a battery module connected in parallel according to the disclosed methods of manufacturing a battery module. FIG. 5B is a schematic diagram illustrating a battery module connected in series according to the disclosed methods of manufacturing a battery module.

The inventors of the present disclosure have found that the following problems occur when batteries having different durability performance are used in combination. That is, when batteries having different durability performance are connected in parallel, the bias of the current load is large, and therefore the battery may rapidly deteriorate. In addition, connecting batteries having different durability performance in series is not preferable from the viewpoint of stability of the battery.

In this regard, the inventors of the present disclosure have found that in the battery module manufactured by the method of the present disclosure, since batteries having similar durability performance are connected in parallel or in series, the above-described problems hardly occur.

For the method of the present disclosure for classifying batteries, reference can be made to the above description of the method of the present disclosure for classifying batteries.

A method of connecting batteries having similar durability performance in parallel or in series is not particularly limited. For example, as illustrated in FIGS. 5A and 5B, the above-described methods of connecting the cells of the rank A, the cells of the rank B, or the cells of the rank C in parallel or in series are exemplified. The method of connecting in parallel or in series is not particularly limited, and a method commonly used in this field can be employed.

### Battery Classification System

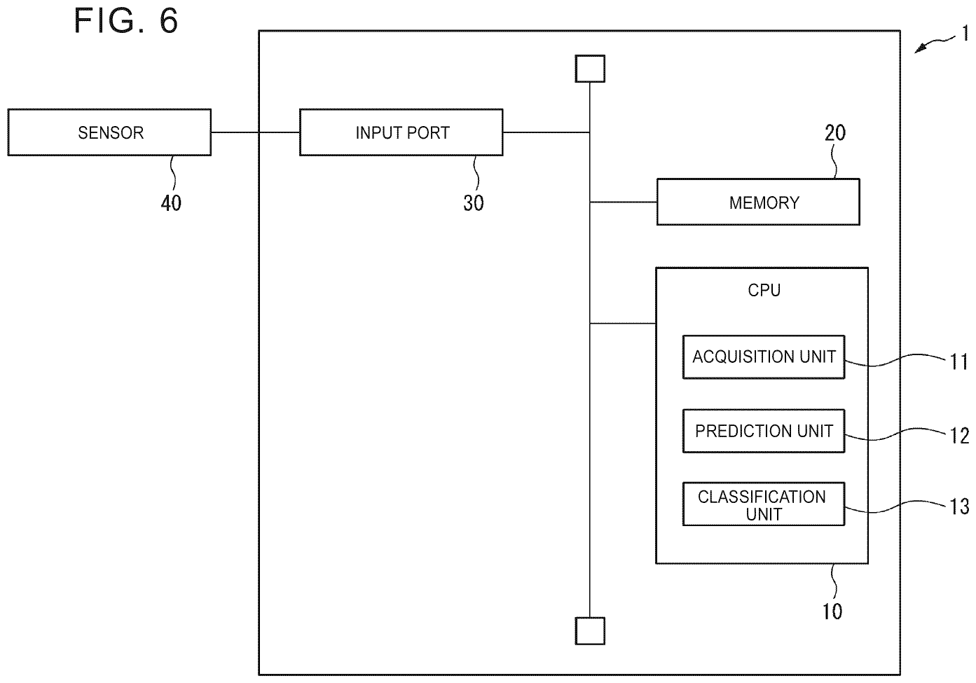

As illustrated in FIG. 6, the battery classification system 1 of the present disclosure includes an acquisition unit 11, a prediction unit 12, and a classification unit 13. The acquisition unit 11 acquires the manufacturing conditions of the plurality of batteries. The prediction unit 12 predicts the durability performance of the plurality of batteries from the manufacturing conditions acquired by the acquisition unit based on the relationship between the manufacturing conditions of the batteries and the durability performance of the batteries. The classification unit 13 classifies the plurality of batteries based on the similarity of the durability performance predicted by the prediction unit. According to the battery classification system of the present disclosure, the method of the present disclosure for classifying a battery can be performed.

As illustrated in FIG. 6, the disclosed battery classification system may include CPU (Central Processing Unit) 10, memory 20, input-port 30, and sensor 40. In this instance, CPU may function as an acquisition unit, a prediction unit, and a classification unit. In CPU, a sensor or the like may be input via an input port.

### Acquisition Unit

The acquisition unit 11 acquires the manufacturing conditions of the plurality of batteries. More specifically, the acquisition unit 11 can acquire the manufacturing conditions of the plurality of batteries on the basis of a signal or the like from the sensor 40 that measures a parameter related to the manufacturing conditions of the batteries. The acquisition unit 11 may be one or more CPU 10 and peripheral circuitry thereof.

When the manufacturing condition is the dew point of the atmosphere at the time of laminating the positive electrode mixture and/or the negative electrode mixture to the base material, the acquisition unit 11 can acquire the dew points as the manufacturing conditions, for example, based on a signal from the dew point sensor.

When the manufacturing condition is a ratio of the basis weight of the positive electrode mixture to the basis weight of the negative electrode mixture, the acquisition unit 11 can acquire the ratio as the manufacturing condition, for example, based on a signal from the mass sensor.

### Prediction Unit

The prediction unit 12 predicts the durability performance of the plurality of batteries from the manufacturing conditions acquired by the acquisition unit 11 based on the relationship between the manufacturing conditions of the batteries and the durability performance of the batteries. For a relationship between the manufacturing conditions of the battery and the durability performance of the battery, reference can be made to the above description of the method of the present disclosure for classifying the battery. This relation may be stored in memory 20, e.g., volatile semiconductor memory (e.g., RAM), non-volatile semiconductor memory (e.g., ROM), hard disk drive (HDD), solid state drive (SSD), or optical recording medium. The prediction unit 12 can predict the durability performance of the plurality of batteries on the basis of the information on the manufacturing conditions of the plurality of batteries acquired by the acquisition unit 11 and the relationship read out from the memory 20. The prediction unit 12 may be one or more CPU (Central Processing Unit) and its peripheral circuitry.

### Classification Unit

The classification unit 13 classifies the plurality of batteries based on the predicted similarity of the durability performance. The classification unit 13 can classify the plurality of batteries based on the information on the similarity of the durability performance predicted by the prediction unit 12. For example, a plurality of batteries can be classified by labeling batteries having similar durability performance, aggregating batteries having similar durability performance, and the like. For how to determine the similarity of durability performance, reference can be made to the above description of the method of the present disclosure for classifying batteries. The classification unit 13 may be one or more CPU (Central Processing Unit) and its peripheral circuitry. The classified data may be stored in the memory 20, for example, a volatile semiconductor memory (e.g., RAM), a non-volatile semiconductor memory (e.g., ROM), a hard disk drive (HDD), a solid state drive (SSD), or an optical recording medium.

What is claimed is:

1. A battery classification method including causing a computer to execute a process comprising:
acquiring a manufacturing condition for a plurality of batteries;
predicting durability performance of the batteries from the acquired manufacturing condition based on relationship between the manufacturing condition of the batteries and the durability performance of the batteries; and
classifying the batteries based on similarity of the durability performance that has been predicted.

2. The method according to claim 1, wherein the manufacturing condition is a dew point of an atmosphere at a time when a positive electrode mixture and/or a negative electrode mixture is laminated on a base material, or a ratio of a basis weight of the positive electrode mixture to a basis weight of the negative electrode mixture.

3. The method according to claim 1, wherein the relationship is relationship specified in advance through machine learning.

4. A battery module manufacturing method comprising connecting the batteries having similar durability performance and classified by the method according to claim 1 in parallel or in series with each other.

5. A battery classification system comprising:
an acquisition unit that acquires a manufacturing condition for a plurality of batteries;
a prediction unit that predicts durability performance of the batteries from the manufacturing condition acquired by the acquisition unit based on relationship between the manufacturing condition of the batteries and the durability performance of the batteries; and
a classification unit that classifies the batteries based on similarity of the durability performance predicted by the prediction unit.
